(19) United States
(12) Patent Application Publication
(10) Pub. No.: US 2026/0305269 A1
(43) Pub. Date: Oct. 1, 2026

(54) DOPED UNDERLAYER SUITABLE FOR EXTREME ULTRAVIOLET RADIATION DOSE REDUCTION

(71) Applicant: ASM IP Holding B.V., Almere (NL)

(72) Inventor: Fatemeh Davodi, Espoo (FI)

(21) Appl. No.: 19/574,603

(22) Filed: Mar. 23, 2026

Related U.S. Application Data
(60) Provisional application No. 63/778,104, filed on Mar. 26, 2025.

(51) Int. Cl. H10P 76/40; G03F 7/00; H10P 14/60; H10P 14/68; H10P 14/692; H10P 76/20

(52) U.S. Cl. CPC H10P 76/4083; H10P 14/68; H10P 14/6938; H10P 76/2041; H10P 76/405; G03F 7/70033; H10P 14/6334

(57) ABSTRACT

Methods and related systems and structures for reducing extreme ultraviolet (EUV) dose requirements during lithography steps. An EUV photoresist may be formed on and in direct physical contact with an underlayer. The combination of the EUV photoresist and the underlayer may be highly sensitive to EUV radiation, potentially allowing a reduced EUV radiation dose to be used to produce photolithographic results similar to results that would normally require a higher EUV radiation dose. The underlayer may be a n-type semiconductor, such as silicon doped with phosphorous.

### CROSS-REFERENCE TO RELATED APPLICATIONS

This application claims priority to U.S. Provisional Patent Application Ser. No. 63/778,104 filed Mar. 26, 2025 titled DOPED UNDERLAYER SUITABLE FOR EXTREME ULTRAVIOLET RADIATION DOSE REDUCTION, the disclosure of which is hereby incorporated by reference in its entirety.

### BACKGROUND

Semiconductor device patterning is often designed around the properties of expensive lithography equipment. Reducing the time needed per wafer during lithography steps can greatly improve throughput and costs of device fabrication, and this time can be expressed in terms of lithography dose.

Dose is equated to energy over a unit space, or in other terms, to the photon flux (number of photons per unit time per unit space) multiplied by the photon energy and exposure time. In the emerging field of extreme ultraviolet (EUV) lithography, which improves resolution through decreased wavelength, the energy per photon is greatly increased. To reduce the dose, either the photon flux or the exposure time needs to be decreased, both of which would reduce the total number of photons hitting the photolithography resists. Moreover, high energy EUV photons are more difficult to absorb by most materials, exaggerating the issue of the low photon count. With such a low number of photons absorbed by the photoresist, it would be difficult to obtain a good quality lithography structure due to the photon shot noise effect, especially at the small structure sizes being pursued. Therefore, the key to practically decreasing dose is to increase the useful effect of each photon.

The usefulness of each photon may be improved through two ways: by increasing the absorption of each photon, and by increasing the number of electrons produced per photon. Absorption is often improved by simply inserting EUV absorbing materials into the lithography structure. This absorption produces photoelectrons which can cause reactions in the photoresist, but one electron per photon conversion still produces high shot noise. This problem is solved if the high energy photoelectrons are converted into multiple secondary electrons (SEs) through multiple possible pathways.

There are two main known solutions to incorporating EUV absorbing and SE producing materials into the lithography stack.

One solution is to directly add the materials to the photoresist such as by adding sensitizers to chemically amplified photoresists (CARs) or by using highly absorbing metal oxide photoresists (MORs). However, there are drawbacks to these new photoresists. Photoresists have become complicated structures that are difficult to control SE generation, and too high of an absorption in the photoresist can block further photons from traveling to the bottom of the photoresist where needed. Too long of an electron path in the photoresist is also not desired as this would result in reduced pattern resolution and increased pattern roughness. If absorption is balanced so that photons are absorb at the photoresist bottom, SEs would still often lost to the substrate.

The second solution to compliment the above solution is to deposit the EUV absorbing and SE producing materials into the underlayers. These layers can be directly designed to produce many electrons and help to supply SEs to the photoresist bottom. However, many of the materials are heavy metals with self-limiting effects because electrons from deeper levels cannot easily move to the photoresist. Moreover, many of the randomly moving electrons are still lost to the substrate. Even if materials with longer electron paths are placed under these materials, electrons would still be blocked by the upper layers and lost to the substrate. Although many high absorption materials are known and can be deposited, a more precisely designed architecture is needed to control how the electrons are produced and whether they end up where needed, all while being incorporated into a low cost and very thin sacrificial patterning stack.

### SUMMARY

Disclosed are structures that can be used as, or employed in, lithographical patterning stacks during processing of semiconductor wafers. Also disclosed are methods and systems for producing such structures.

Advantageously, the structures, when exposed to extreme ultraviolet (EUV), may efficiently produce a large quantity of secondary electrons, thus potentially reducing the EUV dose needed to obtain a desired lithographic structure.

According to aspects described herein, such a structure may comprise a substrate and an EUV photoresist, with an underlayer disposed between the substrate and the EUV photoresist. The EUV photoresist may comprise, for example, a metal oxide photoresist, a metalorganic framework photoresist, or a chemically-amplified photoresist. The underlayer may be in direct physical contact with one or more portions of the EUV photoresist, and the contact point(s) between them may form a p-n junction. The underlayer may act as an EUV dose-reducing layer. For example, the underlayer may interact with the EUV photoresist to allow the amount of EUV dose needed, to achieve a particular quality of photolithographically-produced pattern, to be reduced as compared with a different (e.g., traditional) underlayer. The underlayer may comprise, for example, a main component and at least one dopant. The main component may comprise, for example, an elemental semiconductor such as intrinsic silicon. As further examples, the main component may comprise n-doped silicon, intrinsic silicon-germanium (SiGe), p-doped SiGe, or silicon-on-glass (SoG). The at least one dopant may cause the underlayer to be n-type doped (n-doped, also known as n+). For example, the underlayer may comprise a silicon layer doped with phosphorous, arsenic, or antimony, or other Group V elements. The main component may be doped with the dopant by an amount of, for example, 10%. However, the main component may be doped with the dopant by any amount.

According to further aspects as described herein, such a structure may be produced by performing a method comprising, providing the substrate to a reaction chamber, forming the underlayer on the substrate, and, forming an EUV photoresist on the underlayer. The underlayer and the EUV photoresist may be formed such that the underlayer is in contact with the EUV photoresist and such that a p-n junction exists at the point(s) of contact. Upon the structure being exposed to EUV (e.g., through a mask formed above the EUV photoresist), the EUV photoresist may generate secondary electrons that are drawn toward the p-n junction. Likewise, holes may be drawn from the underlayer toward the p-n junction. This may improve the extraction of photogenerated electrons, potentially reducing the EUV dose that is needed to result in a lithographic pattern with a desired quality (e.g., resolution and/or roughness).

These and other features and advantages are described in greater detail below. This Summary is provided merely to introduce examples of some of the concepts described herein in a simplified form. This Summary is not intended to identify key features or essential features of the claimed subject matter, nor is it intended to be used to limit the scope of the claimed subject matter.

### BRIEF DESCRIPTION OF THE DRAWINGS

FIG. 1 is a side-view cross-section of an example structure 100 according to aspects described herein.

FIG. 2 is a schematic of a system 200 according to aspects described herein.

FIG. 3 is a side-view cross-section of an example interface between an underlayer and an EUV photoresist, according to aspects described herein.

FIG. 4 is a flowchart for an example semiconductor device process according to aspects described herein.

FIG. 5 is a side-view cross-section of an example structure 500 according to aspects described herein.

FIG. 6 is a graph showing experimentally-determined relationships between EUV dose and resulting pattern line edge roughness for various example underlayer materials, according to aspects described herein.

It will be appreciated that elements in the figures are illustrated for simplicity and clarity and are not necessarily drawn to scale. For example, the dimensions of some of the elements in the figures may be exaggerated relative to other elements to help improve understanding of illustrated embodiments of the present disclosure.

### DETAILED DESCRIPTION

The accompanying drawings and descriptions provide examples. It is to be understood that the examples shown in the drawings and/or described are non-exclusive, and that features shown and described may be practiced in other examples.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Examples of seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, may include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

The drawings referenced herein are not meant to be actual views of any particular material, structure, or device, but are merely idealized representations that are used to describe various examples.

The particular implementations shown and described are merely illustrative and are not intended to otherwise limit the scope of the various concepts, features, structures, processes, or any other aspects described herein in any way. For the sake of brevity, conventional manufacturing, connection, preparation, and other functional aspects of the system are not necessarily described in full detail. Furthermore, connecting lines shown in the various figures are intended to represent exemplary functional relationships and/or physical couplings between the various elements. Many alternative or additional functional relationships and/or physical couplings may be present or absent, depending upon specific implementation.

It is to be understood that the configurations and/or approaches described herein are merely illustrative in nature, and that these specific configurations and/or approaches are examples that are not to be considered limiting, because numerous variations thereof are possible. The specific routines or methods described herein may represent one or more of any number of processing strategies. Thus, the various acts illustrated and/or described herein may be performed in the sequences illustrated, in other sequences, or omitted in some cases.

Any of the aspects described herein may be used in any combination or subcombination, as well as any and all equivalents thereof.

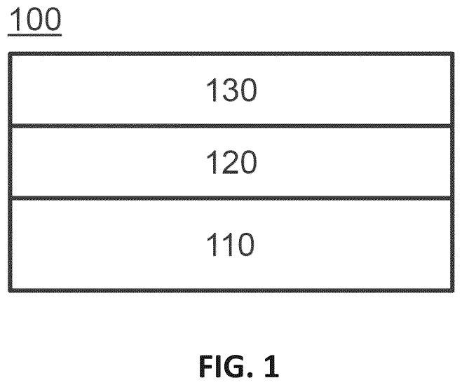

FIG. 1 shows an example structure 100. The structure 100 may comprise a substrate 110, an extreme ultraviolet (EUV) photoresist 130, and an underlayer overlying the substrate 120, such that the EUV photoresist 130 overlies the underlayer 120. The underlayer 120 may comprise a doped semiconductor. The doped semiconductor may comprise a main component and a dopant.

The EUV photoresist 130 may be a layer constructed and arranged for absorbing EUV radiation and generating secondary electrons in response to absorbing the EUV radiation. The EUV photoresist may include any suitable photoresist material, such as molecular, metalorganic, metal oxide, or chemically amplified photoresist. The EUV photoresist 130 may be formed using, for example, any suitable deposition technique, including chemical vapor deposition (CVD), plasma-enhanced chemical vapor deposition (PECVD), atomic layer deposition (ALD), and plasma-enhanced atomic layer deposition (PEALD).

The dopant in the doped semiconductor of the underlayer 120 may increase the conductivity of the doped semiconductor as compared with an undoped variant. Some level of electrical conductivity may advantageously allow replenishing electrons lost to secondary electron emission processes, which may improve secondary electron generation in the underlayer 120, which can in turn assist with lowering the EUV dose needed to achieve sufficient photoresist exposure.

Incorporating a dopant in the underlayer 120 may also reduce the electron affinity of the underlayer, as compared with an undoped version. Doping of the underlayer 120 may therefore increase the electron escape probability, which may in turn result in production of more secondary electrons.

The underlayer 120 may be formed on the substrate 110 by means of any suitable method, for example by means of atomic layer deposition (ALD) or chemical vapor deposition (CVD).

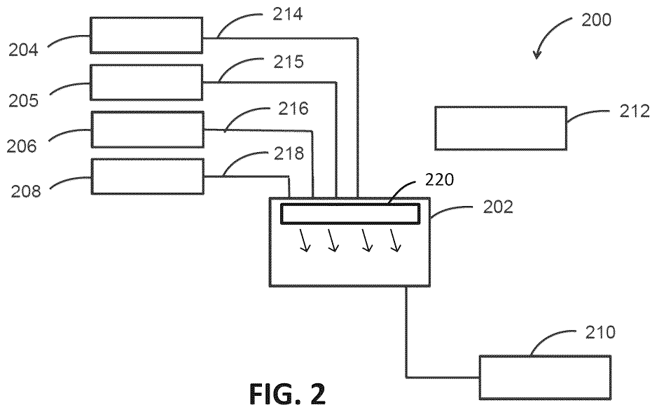

FIG. 2 is a schematic of a system 200 that comprises one or more reaction chambers 202, a first precursor gas source 204, a second precursor gas source 205, a reactant gas source 206, a purge gas source 208, an exhaust 210, and a controller 212.

The one or more reaction chambers 202 may each include any suitable reaction chamber, such as an ALD or CVD reaction chamber.

The first precursor gas source 204 may include a vessel containing one or more precursors as described herein-alone or mixed with one or more carrier (e.g., noble) gases. The second precursor gas source 205 may comprise a vessel containing one or more reactants as described herein-alone or mixed with one or more carrier gases.

The purge gas source 208 may comprise a vessel containing one or more noble gases. Although illustrated with four gas sources 204-208, the system 200 may include any suitable number of gas sources. The gas sources 204-208 may be physically coupled to the one or more reaction chambers 202 via gas lines 214-218, which may each include flow controllers, valves, heaters, and/or the like. The exhaust 210 may comprise one or more vacuum pumps.

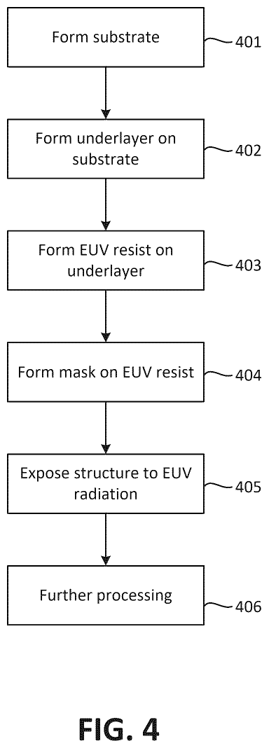

The controller 212 may comprise electronic circuitry, FPGAs, ASICs, processors, memory storing computer-executable instructions (e.g., software or firmware), and/or other components configured to selectively operate valves, manifolds, heaters, pumps and other components included in the system 200. The computer-executable instructions, when executed by one or more processors of the controller 212, may cause the controller 212 to perform any of the functions and operations thereof as described herein, including but not limited to the steps of FIG. 4. For example, the controller 212 may operate to introduce precursors and purge gases from the respective sources 204-208. The controller 212 may control timing of gas sequences, temperature of the one or more reaction chambers 202 and/or of the substrate therein, pressure within the reaction chamber, and/or various other operations to provide proper operation of the system 200. The controller 212 may electrically and/or pneumatically control valves to control flow of precursors, reactants and purge gases into and out of the one or more reaction chambers 202.

One or more reaction chambers, of the one or more reaction chambers 200, may comprise an EUV radiation source 220. The EUV radiation source 220 may be configured to expose a structure within the respective reaction chamber to a dose of EUV radiation. The dose, timing, and/or precise wavelength of the EUV radiation, as well as the operation of the EUV radiation source 220, may be controlled by the controller 212. For example, where a structure comprises an EUV photoresist layer and a mask on top of the photoresist layer, the controller 212 may cause the EUV radiation source 200 to expose the mask and the photoresist layer with EUV radiation at a prescribed reduced EUV dose that is determined by the controller 212.

Other configurations of the system 200 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the one or more reaction chambers 202. As FIG. 2 is a schematic representation of a system, many components have been omitted in the drawing for simplicity of illustration; such components may include, for example, various valves, manifolds, purifiers, heaters, containers, vents, and/or bypasses.

During operation of the reactor system 200, substrates, such as semiconductor wafers (not illustrated), may be transferred from, e.g., a substrate handling system to the one or more reaction chambers 202. Once substrate(s) are transferred to a reaction chamber of the one or more reaction chambers 202, one or more gases from the gas sources 204-208, such as precursors, reactants, carrier gases, and/or purge gases, are introduced into the reaction chamber 202.

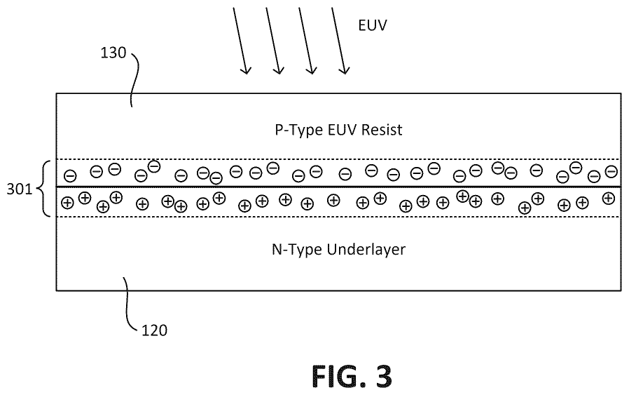

FIG. 3 is a side-view cross-section of an example interface between the underlayer 120 and the EUV photoresist 130. The underlayer 120 and the EUV photoresist 130 may be in direct physical contact with each other at one or more locations. While the two layers 120 and 130 are shown as continuous layers in the drawing, the layers 120 and/or 130 may each be a continuous layer or made up of multiple disconnected sections of layer. Moreover, the layers 120 and/or 130 may each be patterned with a continuous or discontinuous pattern, and may each be of a uniform thickness or of a varied thickness.

The underlayer 120 may comprise, for example, a main component and at least one dopant. The main component may comprise, for example, an elemental semiconductor such as intrinsic silicon. As further examples, the main component of the underlayer 120 may comprise n-doped silicon, intrinsic silicon-germanium (SiGe), p-doped SiGe, or silicon-on-glass (SoG). The at least one dopant may comprise, for example, phosphorous. For example, the underlayer 120 may comprise silicon doped with phosphorous. The main component of the underlayer 120 may be doped with the dopant by an amount in the range of, for example, 10% to 15%, inclusive, or by a higher amount such as greater than 15%. In embodiments, the main component may be doped with phosphorous at levels below 10%. For example, the phosphorous doping level may be in the range of about 3% to less than 10%, including specific implementations at about 5%. However, the main component of the underlayer 120 may be doped with the dopant by any amount. The amount that provides the best results may depend upon the particular implementation and particular semiconductor structure used and desired, as well as depend upon the particular main component and dopant used to produce the underlayer 120.

The dopant may cause the underlayer 120 to become an n-doped semiconductor. For example, doping silicon with phosphorous may result in an n-doped silicon underlayer 120. Other examples of dopants that may be used for silicon in the underlayer 120 include arsenic, antimony, or other Group V elements. As indicated previously, the EUV photoresist 130 may be, for example, a metal oxide photoresist, a metalorganic framework photoresist, or a chemically-amplified photoresist. A depleted region 310 may form at the interface between the EUV photoresist 130 and the underlayer 120.

Depending on the materials selected for the EUV photoresist 130 and the underlayer 120, the underlayer 120 may act as an EUV dose-reducing layer for the EUV photoresist 130. In other words, the underlayer 120 may be configured such that only a reduced EUV dose is needed to be applied to the top of the EUV photoresist 130, as compared with a differently-configured underlayer (e.g., a traditional underlayer), to achieve a particular quality of the patterning of the EUV photoresist 130. This is because the two layers may interact at (and near) the depleted region 310 to form a new material at their interface. This new material may have properties different from the respective properties of the underlayer 120 and of the EUV photoresist 130. Materials selection for the EUV photoresist 130 and the underlayer 120 may be based on factors such as their respective electron distribution and band gaps, as well as the electric field expected to be formed at their interface and/or the diffusion that may be expected to develop at the interface.

It has been observed that, upon light excitation, metal-organic framework (MOF) behaves as a semiconductor and undergoes charge separation, such that electrons and holes are separated. MOF has a similar structure as metal organic photoresist (MOR). Thus, it may be hypothesized that MOR would also behave as a semiconductor, and undergo charge separation, in a manner similar to MOF. Such behavior is expected to occur based on an extension of the knowledge that amorphous-carbon films, rich in sp2 bonds, are p-type semiconductors. The possible correlation between sp2 hybridization in an underlayer (such as the underlayer 120) and EUV dose reduction may be understood by considering molecular binding behavior and electronic band structure of materials. Based on electronic band theory, thick amorphous-carbon films can be considered to be semiconductors due to their sp2 bonding. For example, a diamond's structure is composed of sp 3 C-C bonding that has a band gap of about 6 eV, and the structure is an insulator because the σ and empty σ* states do not touch in the electronic band structure. In contrast, π and empty π* states form bands. Generally, the π state is known to be found in the electronic band structure of graphene. This means that amorphous carbon may affect electrical properties in a way that depends on the ratio of sp2 bonding.

When a p-n junction is formed between the p-type EUV photoresist 130 and the n-type underlayer 120, electrons from the n-type underlayer 120 diffuse towards the p-type EUV photoresist 130, while holes from the p-type EUV photoresist 130 diffuse towards the n-type underlayer 120. This diffusion creates a charge concentration gradient around the p-n junction, forming the depletion region 301 where mobile charge carriers are depleted. The depletion leaves behind fixed positive ions on the n-side (the underlayer 120) and negative ions on the p-side (the EUV photoresist). This charge separation establishes an electric field directed from the p-side to the n-side, causing a drift current that opposes the diffusion current. This dynamic balance between diffusion and drift currents is characteristic of a p-n junction.

FIG. 4 is a flowchart showing example steps that may be performed as part of a semiconductor processing (e.g., manufacturing) process. One or more of the steps may be performed using manufacturing equipment such as the system 200 and/or other known semiconductor manufacturing equipment. Some or all of the steps of FIG. 4 may be controlled by the controller 212. For example, the controller 212 may operate to introduce various precursors and gases from the respective sources 204-208 in appropriate sequences and with appropriate timings and temperatures in the one or more reaction chambers 202 to perform one or more of the steps of FIG. 4. At step 401, the substrate 110 may be formed, for example, in the one or more reaction chambers 202. The formation of the substrate 110 may involve one or more sub-steps to form one or more sub-layers of the substrate 110. Such sub-steps may include, for example, growing a silicon crystal such as using the Czochralski process, doping, epitaxy, physical vapor deposition (PVD), chemical vapor deposition (CVD), plasma-enhanced chemical-vapor deposition (PECVD), cleaning, polishing, furnace oxidation, etc.

At step 402, the underlayer 120 may be formed on the substrate 110, for example in the one or more reaction chambers 202. For example, the underlayer 120 may be formed on the substrate 110 using a cyclical process such as atomic layer deposition. For example, a silicon layer may be formed on the substrate 110. Forming the underlayer may further include doping the underlayer in a manner that may allow the EUV radiation dose to be reduced. For example, as discussed herein, the underlayer may have a main component of silicon and a dopant of phosphorous. Thus, step 402 may further include doping the silicon layer with phosphorous to form an n-doped underlayer 120. For example, the silicon layer may be exposed, in the reaction chamber 202, to phosphorous ions.

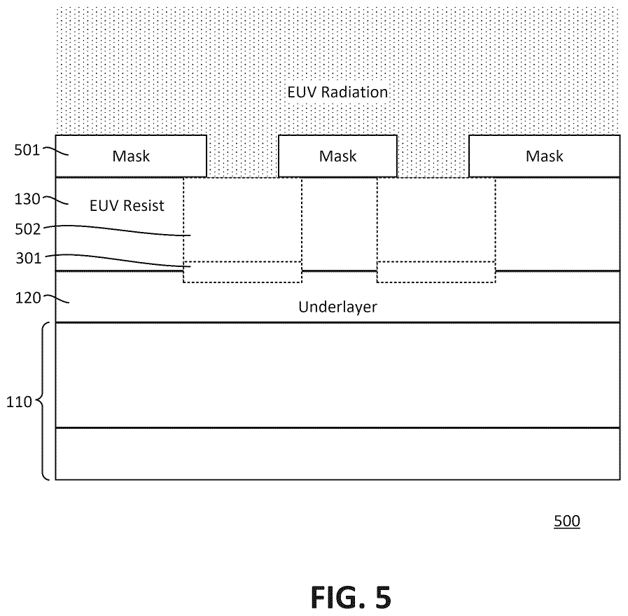

At step 403, the EUV photoresist 130 may be formed on the underlayer 120, for example in the one or more reaction chambers 202. For example, the EUV photoresist 130 may be formed by spin-coating the EUV photoresist onto the underlayer 120 or by depositing the EUV photoresist by a vapor-phase deposition process like a molecular layer deposition process. At step 404, a mask may be formed on the EUV photoresist, for example in the one or more reaction chambers 202. For example, referring to FIG. 5, a mask 501 may be formed on the EUV photoresist. The mask 501 may be patterned to allow the EUV radiation to be absorbed by on one or more portions of the EUV photoresist 130, while blocking one or more other portions of the EUV photoresist 130 from receiving and absorbing the EUV radiation. At step 405, the resulting structure may be exposed to EUV radiation, for example in the one or more reaction chambers 202 by the EUV radiation source 220. The dose of EUV radiation produced by the EUV radiation source 220 may be controlled by the controller 212, and may be set to a reduced EUV dose that is determined based on the chemistry of the underlayer 120 and/or the EUV photoresist 130. For example, the EUV dose may be determined (e.g., by the controller 212 and/or in accordance with user input to the controller 212) based on one or more characteristics of the underlayer 120 and/or the EUV photoresist 130 being exposed. For example, if the underlayer 120 is n-doped (for example by doping silicon with phosphorous), then the EUV dose may be reduced from a standard EUV dose by a predetermined amount or to a predetermined reduced dose value, where the predetermined amount of reduction or the predetermined reduced dose value may be associated with the underlayer 120 being an n-doped underlayer or being a phosphorous-doped underlayer, and/or based on an amount of n-doping or phosphorous-doping of the underlayer. While there is not necessarily a linear relationship between dopant level in the underlayer and EUV dose reduction, it has been found that an EUV dose reduction of approximately 37% can be achieved for a phosphorous-doped Si underlayer as compared with an undoped Si underlayer.

At step 406, one or more further processing steps may be performed (for example in the one or more reaction chambers 202) such as chemical stripping, plasma stripping, etching, cleaning, and/or repeating some or all of the steps of FIG. 4 to form still further layers on top of the structure.

FIG. 5 is a cross-sectional side view of a semiconductor structure 500 that may be formed while being exposed to EUV radiation. The semiconductor structure 500 may include the semiconductor structure 100 (which includes the substrate 100, the underlayer 120, and the EUV photoresist 130) as well as one or more other layers including a mask 501 disposed on the EUV photoresist 130. As discussed above, the mask 501 may be patterned to allow EUV radiation to be absorbed by one or more portions of the EUV photoresist 130, while blocking one or more other portions of the EUV photoresist 130 from receiving and absorbing the EUV radiation. When the structure 500 is exposed to EUV radiation, the exposed areas of the EUV photoresist 130 that absorb the EUV radiation and, as a result, generate secondary electrons. For example, secondary electrons may be generated in exposed region 502 of the EUV photoresist 130 as a result of the EUV radiation. Secondary electrons may also be generated in the underlayer 120 as well as in the substrate 110. The secondary electrons generated in the EUV photoresist 130 may be attracted toward the substrate. Secondary electron generation in the various layers may cause charge to accumulate and form the depletion region 301 between the EUV photoresist 130 and the underlayer 120. Such secondary electron generation and resulting charge accumulation may increase the photoelectric interaction that is experienced the EUV-exposed regions. This is because the secondary electron generation may effectively amplify the effects of the EUV radiation, allowing the photolithographic process to be more sensitive to a given dose of EUV radiation. By selecting an appropriate chemical composition of the underlayer 120 in combination with the EUV photoresist 130, the EUV radiation dose thus may be reduced while still enjoying a desired level of photolithographic pattern quality.

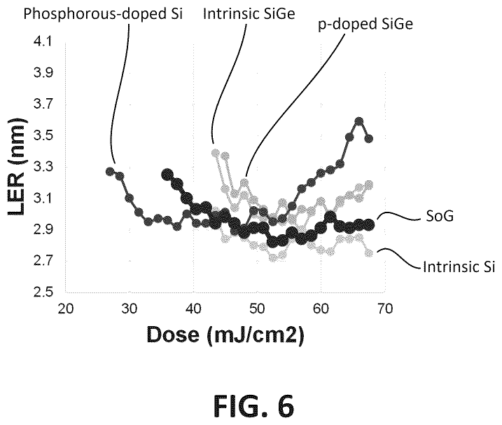

The EUV dose sensitivity, and resulting EUV dose reduction, has been experimentally determined for a variety of different underlayer chemical compositions. For example, FIG. 6 is a graph showing experimentally-determined relationships between EUV dose and resulting pattern line edge roughness (LER) for various example underlayer materials, according to aspects described herein. In general, a lower LER value is more desirable. The graph of FIG. 6 shows EUV dose on the horizontal x axis, in units of mJ/cm², versus LER on the vertical y axis, in units of nm. In this example, experimental results are shown for each of an underlayer made of: phosphorous-doped silicon (Si), intrinsic silicon-germanium (SiGe), p-doped SiGe, silicon-on-glass (SoG), and intrinsic Si. It can be seen from the graph of FIG. 6 that phosphorous-doped Si achieves a given LER with a significantly lower EUV dose as compared with the other chemical makeups of the underlayer. It has further been experimentally found that doping Si with phosphorous in the amount of about 10%, or in the range of about 10% to 15%, inclusive, allows for a significant amount of EUV dose reduction while maintaining a given LER. However, depending upon the implementation, other dopant percentages may be used. It is noted that the experimental results of FIG. 6 were measured using a particular lithographic pattern (the same lithographic pattern as used for the results of FIG. 6), and that other lithographic patterns may produce different results. However, as can be seen from the graph of FIG. 6, phosphorous-doped Si may allow the dose of EUV radiation to be less than 40 mJ/cm² while maintaining a low LER. For example, the EUV radiation may be dosed in the range of about 32 mJ/cm² to about 39 mJ/cm² while maintaining an LER of 3.0 nm or lower. Other ranges of EUV dose and resulting LER are self-evident from the graph of FIG. 6. The EUV exposure dose is not limited to the example values recited herein and encompasses any dose, higher or lower, that achieves the desired lithographic performance for a given implementation.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the descriptions herein. Accordingly, the foregoing description is by way of example only, and is not limiting.

1. A method comprising:
forming an underlayer on a substrate; and
forming an extreme ultraviolet (EUV) photoresist on the underlayer,
wherein the underlayer is in contact with the EUV photoresist and comprises silicon doped with phosphorous.

2. The method of claim 1, wherein the silicon is doped with phosphorous by an amount in a range of 10% and 15%, inclusive.

3. The method of claim 1, wherein the silicon is doped with phosphorous by an amount greater than 15%.

4. The method of claim 1, wherein the forming the underlayer comprises:
forming a silicon layer on the substrate; and
doping the silicon layer with phosphorous.

5. The method of claim 1, wherein the forming the EUV photoresist comprises spin-coating the EUV photoresist onto the underlayer.

6. The method of claim 1, wherein the forming the EUV photoresist comprises depositing the EUV photoresist by a vapor-phase deposition process.

7. The method of claim 1, wherein a p-n junction is formed at a contact point between the EUV photoresist and the underlayer.

8. The method of claim 1, wherein the EUV photoresist comprises a metal organic photoresist.

9. The method of claim 1, wherein the EUV photoresist comprises a metal oxide photoresist.

10. A method comprising:
providing a substrate to a reaction chamber;
introducing, in the reaction chamber, at least one precursor to form, via epitaxy, a silicon layer on the substrate;
exposing, in the reaction chamber, the silicon layer to phosphorous ions to produce a phosphorous-doped silicon layer; and
depositing an extreme ultraviolet (EUV) photoresist on, and in contact with, the phosphorous-doped silicon layer.

11. The method of claim 10, wherein the exposing the silicon layer to phosphorous ions causes the silicon layer to be doped with phosphorous by an amount in a range of 10% and 15%, inclusive.

12. The method of claim 10, wherein the exposing the silicon layer to phosphorous ions causes the silicon layer to be doped with phosphorous by an amount greater than 15%.

13. The method of claim 10, wherein the depositing the EUV photoresist comprises spin-coating the EUV photoresist onto the phosphorous-doped silicon layer.

14. The method of claim 10, wherein the depositing the EUV photoresist comprises depositing the EUV photoresist by a vapor-phase deposition process.

15. The method of claim 10, wherein a p-n junction is formed at a contact point between the EUV photoresist and the phosphorous-doped silicon layer.

16. The method of claim 10, wherein the EUV photoresist comprises a metal organic photoresist.

17. The method of claim 10, wherein the EUV photoresist comprises a metal oxide photoresist.

18. A system comprising:
a controller;
a reaction chamber; and
an extreme ultraviolet (EUV) radiation source configured to radiate EUV radiation within the reaction chamber,
wherein the controller is configured to cause the EUV radiation source to expose a semiconductor structure, comprising a substrate, an underlayer, and an EUV photoresist disposed on the underlayer, with a reduced EUV dose that is based on a phosphorous doping of the underlayer.

19. The system of claim 18, wherein the reduced EUV dose is based on an amount of phosphorous doping of the underlayer.
